(19) United States
(12) Patent Application Publication
(10) Pub. No.: US 2025/0335024 A1
(43) Pub. Date: Oct. 30, 2025

(54) EYE OPENING MONITOR CIRCUIT WITH FEEDBACK LOOP AND EYE OPENING MONITORING METHOD

(71) Applicant: RAMSCHIP, INC., Seongnam-si (KR)

(72) Inventors: Jaegan KO, Seongnam-si (KR); Jeonghyu YANG, Seongnam-si (KR); Bongjoon LEE, Seongnam-si (KR)

(21) Appl. No.: 18/760,194

(22) Filed: Jul. 1, 2024

(30) Foreign Application Priority Data
Apr. 30, 2024 (KR) 10-2024-0058145

(51) Int. Cl. G06F 3/01; G06V 40/18

(52) U.S. Cl. CPC G06F 3/013; G06V 40/18

(57) ABSTRACT

An eye opening monitor circuit with a feedback loop configured to measure information for generating an eye diagram with respect to at least one point of a transmission apparatus or reception apparatus may include a first sampler; a second sampler; a comparison block; and a control logic block, wherein the second sampler, the comparison block, and the control logic block form a loop, thereby having a useful effect capable of shortening a time required to generate the eye diagram.

### BACKGROUND OF THE INVENTION

### Field of the Invention

The present disclosure relates to an eye opening monitor technology in a high-speed signal transmission and reception apparatus.

### Background of the Related Art

An eye opening monitor (EOM, or eye monitor) is a tool for evaluating signal quality in a high-speed signal transmission and reception apparatus or high-speed signal transmission and reception system. That is, the performance of a communication channel may be quantitatively measured using an EOM, and the reliability of a communication system and data may be improved based on data measured by utilizing the EOM. The EOM may be mainly divided into 1-D (checking signal quality in a time or voltage axis) and 2-D (checking signal quality in both time and voltage axes) types, and selected as a type that matches the kind and requirements of an application.

An EOM circuit may determine an error by utilizing a probing point. The EOM circuit may be divided into 1-D (a mask is generated in a time or voltage axis) and 2-D (a mask is generated by including time and voltage axes) types based on the shape of the mask. Although the mask shapes of the 1-D type EOM circuit and the 2-D type EOM circuit are different, both types have in common that the probing point moves to cover all data points.

In general, the higher the resolution of the EOM circuit, the more detailed the eye diagram may be expressed, but it comes with the disadvantage of increased data processing time and increased data storage capacity. In particular, data processing time may be an important consideration in an application that needs to process a large amount of data in real time or sequentially evaluate signal quality for a plurality of data lanes using a single EOM circuit. Therefore, it is necessary to design an EOM circuit that satisfies system requirements, in consideration of a balance between resolution and computational time required to generate an eye diagram.

The above-described background technology is technical information possessed by the inventor for deriving the present disclosure or acquired in the process of deriving the present disclosure, and cannot necessarily be said to be known technology disclosed to the general public prior to filing the application for the present disclosure.

### CITATION LIST

### Patent Literature

(Patent Document 1) KR 10-2275636

### SUMMARY OF THE INVENTION

One aspect of the present disclosure may provide an eye opening monitor circuit with a feedback loop capable of shortening a time required to generate an eye diagram.

In order to achieve the foregoing objective, an eye opening monitor circuit with a feedback loop according to an embodiment of the present disclosure is contrived, and an eye opening monitor circuit configured to measure information for generating an eye diagram with respect to at least one point of a transmission apparatus or reception apparatus may include a first sampler that samples a data value by comparing an input signal with a first reference voltage; a second sampler that samples a data value by comparing the input signal with a second reference voltage V2; a comparison block that compares an output value of the first sampler with an output value of the second sampler to output a comparison result value; and a control logic block that generates a control command signal to change the second reference voltage, wherein the control logic block generates a control command signal to change the second reference voltage in a direction in which a difference between the first and second reference voltages increases when the output value of the first sampler and the output value of the second sampler are the same, and generates a control command signal to change the second reference voltage in a direction in which the difference between the first and second reference voltages decreases when the output value of the first sampler and the output value of the second sampler are different, and the second sampler, the comparison block, and the control logic block form a loop.

Furthermore, the eye opening monitor circuit may further include an edge detector that detects an edge at which the output value of the first sampler changes, wherein the edge detector provides an enable signal to the comparison block when a change in the output value of the first sampler is detected.

Here, the comparison block may include an XOR gate in which an output terminal of the first sampler is connected to a first input terminal and an output terminal of the second sampler is connected to a second input terminal, wherein the control logic block includes a counter connected to an output terminal of the XOR gate, the XOR gate operates when the enable signal is applied thereto, and the control logic block generates the control command signal according to a digital code value of the counter.

Furthermore, the XOR gate may output 0 when input values of the first input terminal and the second input terminal are the same, and output 1 when they are different, wherein the counter increases the digital code value when an output value of the XOR gate is 0, the counter decreases the digital code value when the output value of the XOR gate is 1, and the control logic block generates a control command signal to change the second reference voltage when the digital code value reaches a predetermined value.

Here, the eye opening monitor circuit may further include a reference voltage generator that generates the second reference voltage, wherein the reference voltage generator determines the second reference voltage according to the control command signal.

Furthermore, a ratio of increase and decrease widths of the digital code value may be determined according to a target value of an output error rate, wherein when the target value of the output error rate is a first target value, an eye opening of the eye diagram is relatively small, and when the target value of the output error rate is a second target value greater than the first target value, the eye opening of the eye diagram is relatively large.

Furthermore, the counting information of the counter may consist of a digital code value including most significant bit information and least significant bit information, wherein the most significant bit information is fed back to the loop, the most significant bit information is utilized to generate the eye diagram outside the loop, and the least significant bit information is utilized to increase a resolution of the eye diagram outside the loop.

Furthermore, the eye opening monitor circuit may further include an eye diagram generator that generates an eye diagram using the control command signal, wherein the counting information of the counter consists of a digital code value including most significant bit information and least significant bit information, the most significant bit information is fed back to the loop, the most significant bit information is provided to the eye diagram generator outside the loop and utilized to generate the eye diagram, and the least significant bit information is provided to the eye diagram generator outside the loop and utilized to increase a resolution of the eye diagram.

An eye opening monitoring method according to an embodiment of the present disclosure may include a step A of outputting, by a first sampler, a first digital value sampled by comparing an input signal with a first reference voltage, and outputting, by a second sampler, a second digital value sampled by comparing the input signal with a second reference voltage; a step B of comparing, by a comparison block, the first digital value with the second digital value to output a comparison result value; a step C of generating, by a control logic block, a control command signal to change the second reference voltage; and a step D of being fed back to the step A subsequent to the step C, wherein the control logic block generates a control command signal to change the second reference voltage in a direction in which a difference between the first and second reference voltages increases when the first digital value and the second digital value are the same, and generates a control command signal to change the second reference voltage in a direction in which the difference between the first and second reference voltages decreases when the first digital value and the second digital value are different, and the step C is ended when a predetermined condition is satisfied.

Furthermore, the method may further include a BI step of detecting an edge at which the first digital value changes, wherein the step B is performed when the edge is detected in the step B1.

Here, the comparison block may include an XOR gate, wherein the XOR gate is configured such that an output terminal of the first sampler is connected to a first input terminal and an output terminal of the second sampler is connected to a second input terminal so as to output 0 when the first digital value and the second digital value are the same, and 1 when they are different, wherein the control logic block includes a counter that outputs a digital code value, the counter increases the digital code value when an output value of the XOR gate is 0, the counter decreases the digital code value when the output value of the XOR gate is 1, and the control logic block generates a control command signal to change the second reference voltage when the digital code value reaches a predetermined value.

Furthermore, the method may further include a step E of generating an eye diagram using the control command signal, wherein the counting information of the counter consists of a digital code value including most significant bit information and least significant bit information, the most significant bit information is used to change the second reference voltage, the most significant bit information is utilized to generate the eye diagram in the step E, and the least significant bit information is utilized to increase a resolution of the eye diagram in the step E.

The method may further include, subsequent to carrying out a reference voltage change search process of checking the digital code value when the first digital value and the second digital value become different through repeatedly performing the steps A, B, C and D while increasing the second reference voltage by starting from the center of the eye diagram, maintaining the second reference voltage that is finally used in the reference voltage change search process and changing a phase thereof, and then repeatedly performing the steps A, B, and C.

In an eye opening monitor circuit with a feedback loop according to an embodiment of the present disclosure, an eye opening monitor circuit configured to measure information for generating an eye diagram with respect to at least one point of a transmission apparatus or reception apparatus may include a first sampler that samples a data value by comparing an input signal with a first reference voltage at an edge of a main clock; a second sampler that samples a data value by comparing the input signal with a second reference voltage at an edge of a sub-clock; a comparison block that compares an output value of the first sampler with an output value of the second sampler to output a comparison result value; and a control logic block that generates a phase control command signal to change a phase of the sub-clock, wherein the control logic block generates a phase control command signal to change the sub-clock in a direction in which a difference between the main clock and the sub-clock increases when the output value of the first sampler and the output value of the second sampler are the same, and generates a phase control command signal to change the sub-clock in a direction in which the difference between the main clock and the sub-clock decreases when the output value of the first sampler and the output value of the second sampler are different, and the second sampler, the comparison block, and the control logic block form a loop.

According to one embodiment of the present disclosure, there is a useful effect capable of shortening a time required to generate an eye diagram.

### BRIEF DESCRIPTION OF THE DRAWINGS

FIG. 1 is a diagram for explaining an eye diagram;

FIG. 2 is a block diagram schematically illustrating an eye opening monitor circuit according to an embodiment of the present disclosure;

FIG. 3 is a diagram schematically illustrating an eye opening monitor circuit according to an embodiment of the present disclosure;

FIG. 4 is a diagram for explaining a chiplet structure in which an eye opening monitor circuit is utilized according to an embodiment of the present disclosure;

FIG. 5 is a diagram for explaining an example of utilization of an eye opening monitor circuit according to an embodiment of the present disclosure;

FIG. 6 is a diagram for explaining an example of utilization of an eye opening monitor circuit according to an embodiment of the present disclosure;

FIG. 7 is a diagram for explaining a change in line width of an eye diagram based on a target value of an output error rate in an eye opening monitor circuit according to an embodiment of the present disclosure;

FIG. 8 is a diagram for explaining an operation of an eye opening monitor circuit according to an embodiment of the present disclosure;

FIG. 9 is a diagram for explaining a digital code value of a counter included in an eye opening monitor circuit according to an embodiment of the present disclosure;

FIG. 10 is a diagram schematically illustrating an eye opening monitor circuit according to another embodiment of the present disclosure;

FIG. 11 is a diagram schematically illustrating a signal timing of an eye opening monitor circuit according to another embodiment of the present disclosure;

FIG. 12 is a diagram schematically illustrating an eye opening monitor circuit according to still another embodiment of the present disclosure;

FIG. 13 is a diagram schematically illustrating a signal timing of an eye opening monitor circuit according to still another embodiment of the present disclosure;

FIG. 14 is a diagram for explaining an eye opening monitoring method according to an embodiment of the present disclosure; and

FIG. 15 is a diagram for explaining an eye opening monitoring method according to another embodiment of the present disclosure.

### DETAILED DESCRIPTION OF THE PREFERRED EMBODIMENT

Advantages and features of the present disclosure, and methods of accomplishing the same will be clearly understood with reference to the following embodiments described below in detail in conjunction with the accompanying drawings. However, the present disclosure is not limited to the embodiments which will be disclosed below, but may also be implemented in various different forms. The embodiments may be provided to complete the present disclosure and to allow those skilled in the art to fully understand the category of the disclosure Throughout the specification, the same reference numerals represent the same elements.

It should be noted that the terms used herein are merely used to describe the embodiments, but not to limit the present disclosure. In this specification, unless clearly used otherwise, expressions in a singular form include a plural form. The term “comprise” and/or “comprising” used in the specification intend to express an element, a step, an operation and/or a device does not exclude the existence or addition of one or more other elements, steps, operations and/or devices.

Although first, second, and the like are used to describe various devices or elements, the devices or elements are not, of course, limited to the terms. The terms are merely used to distinguish one device or element from other devices or elements. Therefore, a first device or element mentioned below may also, of course, be a second device or element within the technical concept of the present disclosure.

Unless otherwise defined, all terms (including technical and scientific terms) used in this specification may be used with meanings that can be commonly understood by those skilled in the art to which the present disclosure pertains. Additionally, terms defined in commonly used dictionaries are not interpreted ideally or excessively unless clearly specifically defined.

Hereinafter, the configuration and operational effects of the present disclosure will be described in more detail with reference to the accompanying drawings.

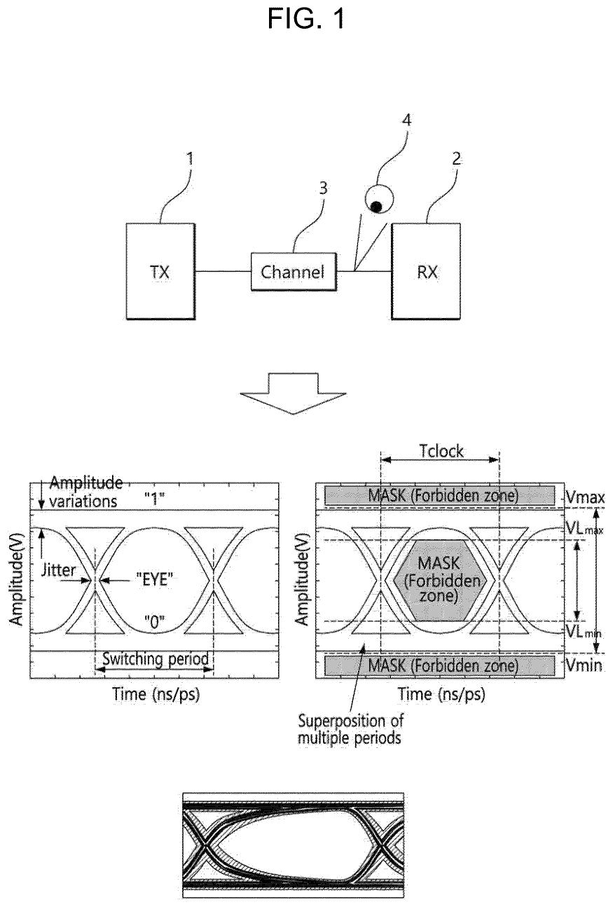

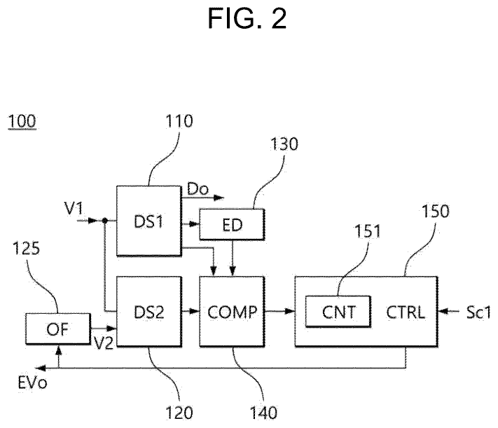

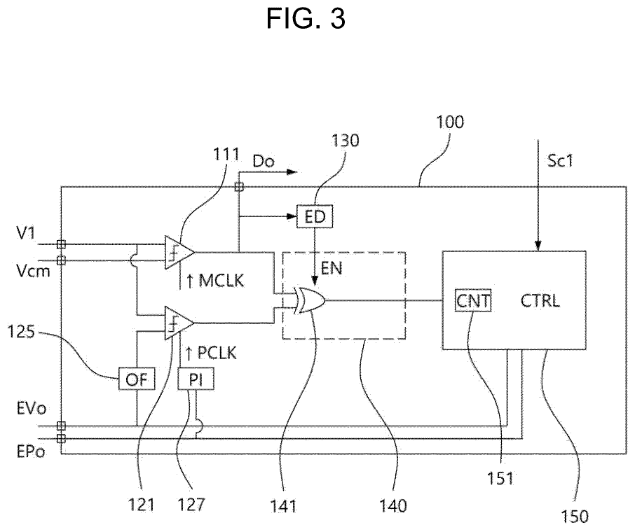

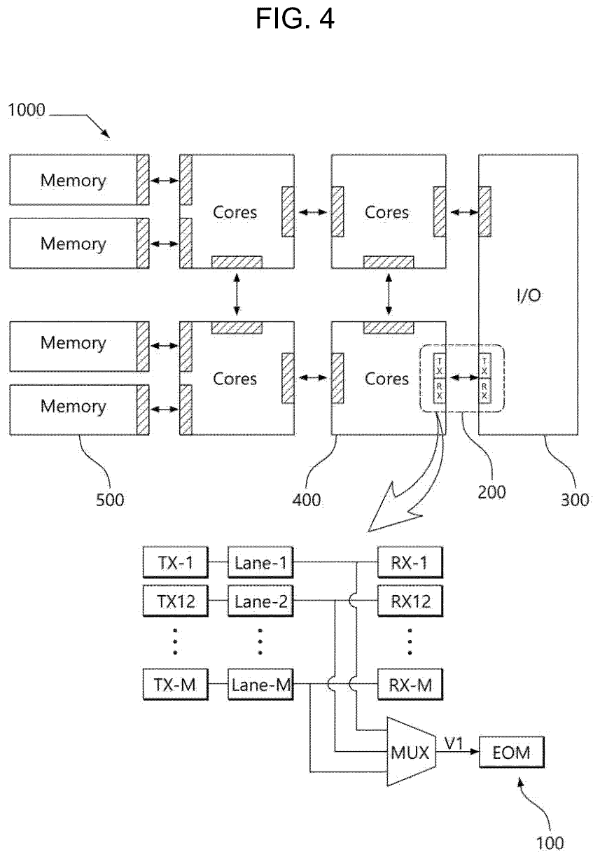

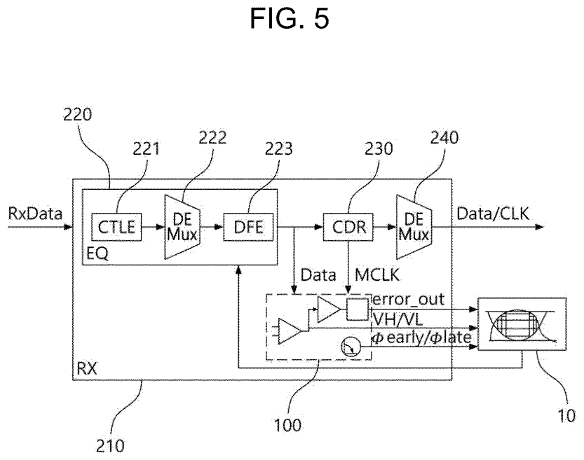

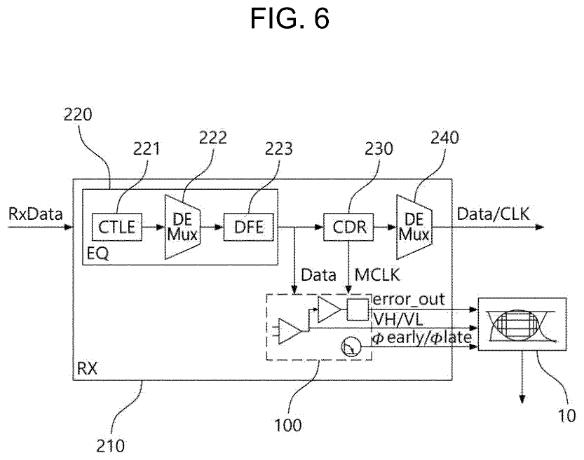

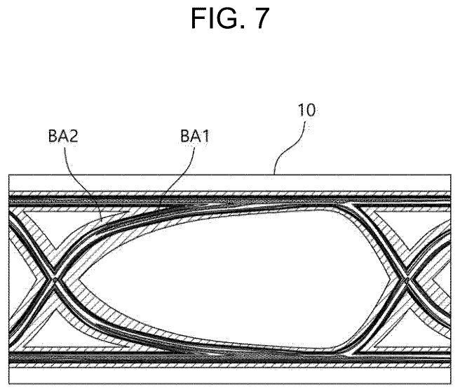

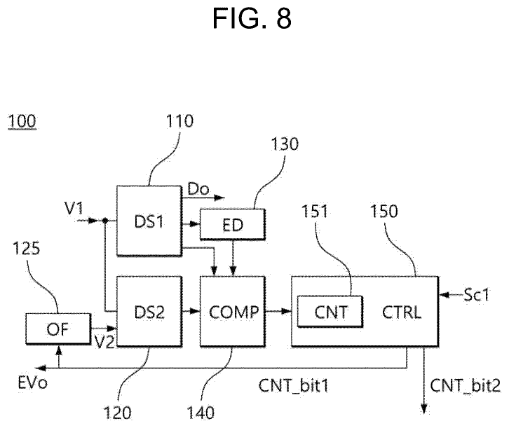

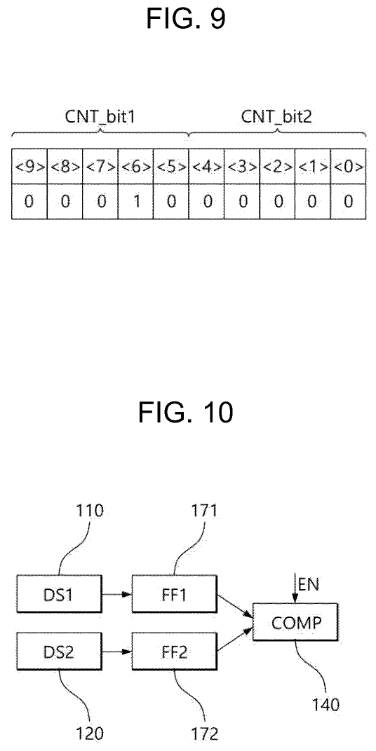

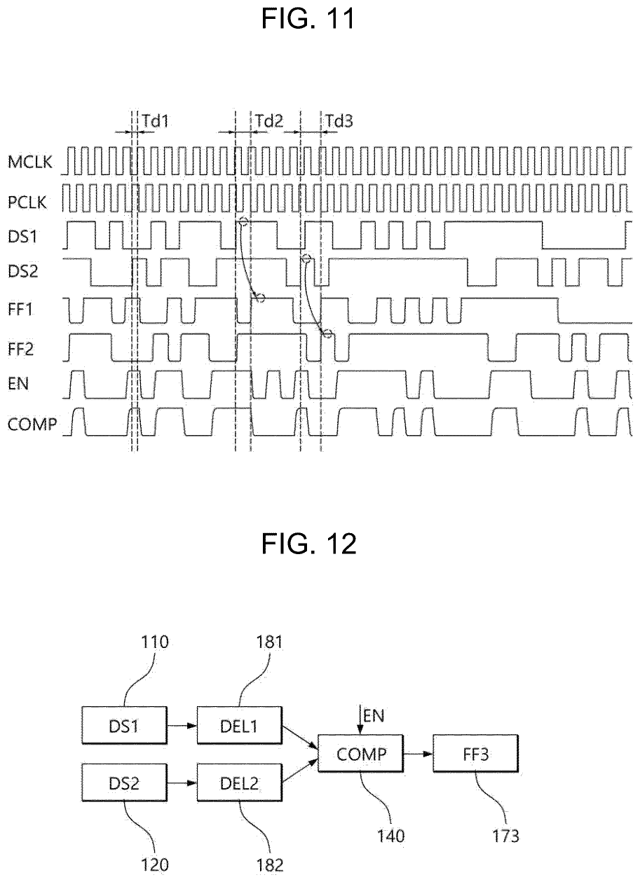

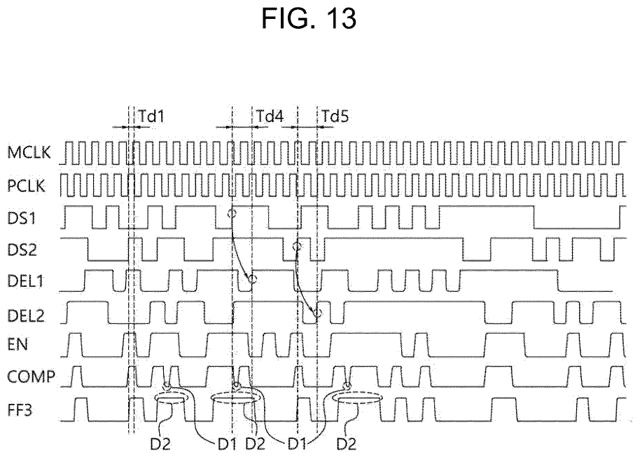

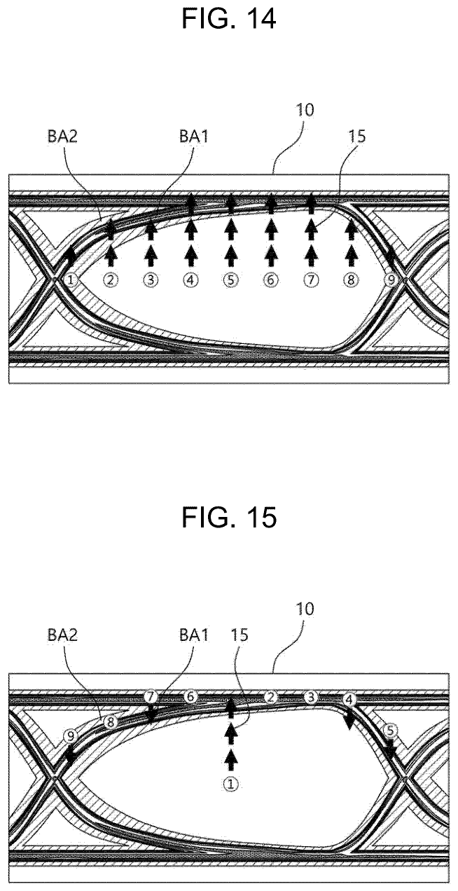

FIG. 1 is a diagram for explaining an eye diagram 10, FIG. 2 is a block diagram schematically illustrating an eye opening monitor circuit 100 according to an embodiment of the present disclosure, FIG. 3 is a diagram schematically illustrating the eye opening monitor circuit 100 according to an embodiment of the present disclosure, FIG. 4 is a diagram for explaining a chiplet structure 1000 in which the eye opening monitor circuit 100 is utilized according to an embodiment of the present disclosure, FIG. 5 is a diagram for explaining an example of utilization of the eye opening monitor circuit 100 according to an embodiment of the present disclosure, FIG. 6 is a diagram for explaining an example of utilization of the eye opening monitor circuit 100 according to an embodiment of the present disclosure, FIG. 7 is a diagram for explaining a change in line width of the eye diagram 10 based on a target value of an output error rate in the eye opening monitor circuit 100 according to an embodiment of the present disclosure, FIG. 8 is a diagram for explaining an operation of the eye opening monitor circuit 100 according to an embodiment of the present disclosure, FIG. 9 is a diagram for explaining a digital code value of a counter 151 included in the eye opening monitor circuit 100 according to an embodiment of the present disclosure, FIG. 10 is a diagram schematically illustrating an eye opening monitor circuit according to another embodiment of the present disclosure, FIG. 11 is a diagram schematically illustrating a signal timing of an eye opening monitor circuit according to another embodiment of the present disclosure, FIG. 12 is a diagram schematically illustrating an eye opening monitor circuit according to still another embodiment of the present disclosure, FIG. 13 is a diagram schematically illustrating a signal timing of an eye opening monitor circuit according to still another embodiment of the present disclosure, FIG. 14 is a diagram for explaining an eye opening monitoring method according to an embodiment of the present disclosure, and FIG. 15 is a diagram for explaining an eye opening monitoring method according to another embodiment of the present disclosure.

Referring to FIG. 1, a transmitter 1 and a receiver 2 may be connected in a wired manner through a communication channel 3. A shape of the eye diagram 10 and terms associated therewith at a point viewed by an eye opening monitor 4 in FIG. 1 are illustrated in FIG. 1.

In one embodiment, the eye opening monitor circuit 100 may include devices for monitoring a waveform with respect to a specific point in a signal reception circuit. The eye opening monitor circuit 100 may operate by receiving a clock signal, sample a waveform at a point to which the eye opening monitor 4 is connected, and output a result thereof. The eye opening monitor 4 shown in FIG. 1 is placed on a side of the receiver 2 in the communication channel 3 to observe a distorted signal passing through the communication channel 3, but the scope of the present disclosure is not limited thereto. In addition, as illustrated in FIG. 5, the eye opening monitor circuit 100 may receive a signal between an equalizer 220 and a clock-data recovery circuit 230 to monitor an eye opening. As a result of monitoring the eye opening in this manner, an eye diagram 10 may be obtained, and the eye diagram 10 may be utilized to adjust a setting value of the equalizer 220 as illustrated in FIG. 5. Additionally, the eye diagram 10 may be utilized for purposes such as outputting information outside a chip and post-processing data through a PC, or the like as illustrated in FIG. 6.

The eye opening monitor circuit 100 with a feedback loop according to an embodiment of the present disclosure includes a first sampler 110, a second sampler 120, a comparison block 140, and a control logic block 150. In one embodiment, the eye opening monitor circuit 100 may further include an edge detector 130, a reference voltage generator 125, and the like.

The first sampler 110 outputs a result of comparing an input signal V1 with a first reference voltage Vcm, and the second sampler 120 outputs a result of comparing the input signal with a second reference voltage V2.

In one embodiment, the first sampler 110 and the second sampler 120 may include comparators, respectively.

In one embodiment, the first sampler 110 may operate according to the main clock MCLK, and the second sampler 120 may operate according to the sub-clock PCLK. Here, the main clock MCLK may refer to a clock used by the receiver 2 to restore data from the input signal V1. In addition, the sub-clock PCLK may be utilized to search a boundary line of the eye diagram 10, and may be generated by a sub-clock generator 127, or the like. In one embodiment, the sub-clock generator 127 may be implemented as a phase interpolator (PI) or the like. In the eye opening monitor circuit 100 according to an embodiment of the present disclosure, a process of searching a boundary line of the eye diagram 10 while changing the second reference voltage V2 at any one phase, changing the phase when the boundary line is confirmed at the corresponding phase, and then searching the boundary line again may be carried out.

In one embodiment, an intermediate value of the input signal V1 may be applied as the first reference voltage Vcm. For instance, if a minimum value of the input signal V1 is 0 V and a maximum value of the input signal V1 is 100 mV, then 50 mV may be set as the first reference voltage Vcm. However, if it is a value between the minimum and maximum values of the input signal V1, then a value other than the intermediate value may be set as the first reference voltage Vcm. However, in this case, the accuracy of determination may be relatively reduced. In one embodiment, the second reference voltage V2 may be set to be offset from the first reference voltage Vcm. In another embodiment, the second reference voltage V2 may be set independently of the first reference voltage Vcm. In addition, the second reference voltage V2 may be generated by the reference voltage generator 125, and when a control command signal EVo being output from the control logic block 150 is applied to the reference voltage generator 125, the reference voltage generator 125 may set or change the second reference voltage V2 to correspond to the control command signal EVo. In one embodiment, the reference voltage generator 125 may be implemented with a digital analog converter (DAC) such as a register DAC. In another embodiment, an additional device may be provided to generate an offset in a differential input transistor for comparison within the sampler (comparator), and a voltage offset may be generated by a method of adjusting a bias current thereof.

Meanwhile, in FIG. 2, the input signal V1 may be a single-ended signal or a differential signal. In one embodiment, in a case where the input signal V1 is a single-ended signal, there must be a reference input voltage, and in a case where the input signal V1 is a differential signal, the reference input voltage may be 0. In the eye opening monitor circuit 100 according to an embodiment of the present disclosure, the input signal V1 is not limited to a single-ended signal, and may also be a differential signal.

In the eye opening monitor circuit 100 according to an embodiment of the present disclosure, a process of searching a boundary line of the eye diagram 10 while changing a phase of the sub-clock PCLK in a state where the second reference voltage V2 is fixed to a predetermined value, changing the value of the second reference voltage V2 when the boundary line is confirmed at the second reference voltage V2 of the corresponding value, and then searching the boundary line again while changing the phase of the sub-clock PCLK may be carried out. Here, the phase of the sub-clock PCLK may be set in a manner of being adjusted based on the main clock MCLK. In another embodiment, the sub-clock PCLK may be set independently of the main clock MCLK. In addition, when the phase control command signal EPo being output from the control logic block 150 is applied to the sub-clock generator 127, the sub-clock generator 127 may set or change the sub-clock PCLK to correspond to the phase control command signal EPo. In another embodiment, the sub-clock PCLK may be adjusted by a control means other than the control logic block 150. Meanwhile, data sampled by the first sampler 110 may be utilized as received data (Do).

In one embodiment, the comparison block 140 compares an output value of the first sampler 110 and an output value of the second sampler 120 to output a comparison result value. In one embodiment, the output value of the first sampler 110 may be defined as a first digital value, and the output value of the second sampler 120 may be defined as a second digital value. In one embodiment, the comparison block 140 may include an XOR gate 141.

In one embodiment, an output terminal of the first sampler 110 is connected to a first input terminal of the XOR gate 141, and an output terminal of the second sampler 120 is connected to a second input terminal of the XOR gate 141.

In one embodiment, when an enable signal EN is applied to the XOR gate 141, the XOR gate 141 may operate, and the enable signal E may be received from the edge detector 130.

In one embodiment, the XOR gate 141 may output 0 when input values of the first input terminal and the second input terminal are the same, and may output 1 when the input values of the first input terminal and the second input terminal are different.

The eye opening monitor circuit 100 according to an embodiment of the present disclosure may further include the edge detector 130. In one embodiment, the edge detector 130 may detect a change in the output value of the first sampler 110. For instance, the edge detector 130 may detect an edge of the input signal by detecting when the output value of the first sampler 110 changes from “1” or “H” to “O” or “L” or vice versa. Additionally, the edge detector may provide an enable signal to the comparison block when an edge is detected. In one embodiment, the enable signal EN may be provided to the XOR gate 141, and when the enable signal EN is applied, a result of comparing the output value of the first sampler 110 with the output value of the second sampler 120 may be output. Through this, cases where the probing point and the data sampling point output the same value due to no occurrence of data transition may be distinguished and excluded from the operation of an eye opening detection loop.

In one embodiment, the control logic block 150 generates a control command signal EVo. The control command signal EVo may include information for setting or changing the second reference voltage V2, and may be provided to the reference voltage generator 125. Additionally, the control command signal EVo may include information required to generate the eye diagram 10. That is, the control command signal EVo may be output information of the eye opening monitor circuit 100. In one embodiment, the control command signal EVo may be related to a magnitude of the second reference voltage V2 and utilized to derive a y-coordinate of the eye diagram 10, and an x-coordinate of the eye diagram 10 may be derived by utilizing a phase value of the sub-clock PCLK. In one embodiment, the output information of the eye opening monitor circuit 100 may be utilized inside the receiver 2 as illustrated in FIG. 5, or utilized in a manner of being output to an outside of the receiver 2 or the chip and post-processed through a PC, or the like as illustrated in FIG. 6.

In one embodiment, the control logic block 150 may include the counter 151. The counter 151 may be connected to the output terminal of the XOR gate 141, and the counter 151 may receive an output value of the XOR gate 141 to perform counting.

In one embodiment, counter 151 may hold a digital code value, an example of the digital code value being schematically illustrated in FIG. 9. That is, the counter 151 may count the output value of the XOR gate 141 using a digital code value consisting of a plurality of bits.

In addition, the counter 151 may increase the digital code value when the output value of the XOR gate 141 is 0. Additionally, the counter 151 may decrease the digital code value when the output value of the XOR gate 141 is 1.

In one embodiment, the control logic block 150 may output a control command signal EVo when the digital code value reaches a predetermined value.

In one embodiment, the control logic block 150 may generate a control command signal EVo to change the second reference voltage V2 in a direction in which a difference between the first reference voltage Vcm and the second reference voltage V2 increases when the output value of the first sampler 110 and the output value of the second sampler 120 are the same, and generate a control command signal EVo to change the second reference voltage V2 in a direction in which the difference between the first reference voltage Vcm and the second reference voltage V2 decreases when the output value of the first sampler 110 and the output value of the second sampler 120 are different.

For instance, assuming that the second reference voltage V2 is greater than the first reference voltage Vcm, when the digital code value of the counter 151 becomes “00001 00000,” the control logic block 150 may generate a control command signal EVo that causes the second reference voltage V2 to increase by a predetermined magnitude and provide the control command signal EVo to the reference voltage generator 125 (a first change of the second reference voltage). Accordingly, the output value of the second sampler 120 is changed, wherein when the changed output value of the second sampler 120 is still the same as the output value of the first sampler 110, the digital code value of the counter 151 increases, but the reference voltage V2 may remain unchanged for a predetermined period of time. Here, the predetermined period of time may a period of time required to repeat changes in the digital code value through the output of the XOR gate 141 and counter counting until a predetermined condition is satisfied. That is, the above-described predetermined period of time may be adjusted by setting a minimum value of the digital code value of the counter 151 that changes the second reference voltage V2. In a high-speed communication system, the frequency of the main clock MCLK ranges from several to tens of GHz, so the output of a result value of the XOR gate 141 proceeds at a fairly high speed, wherein a speed at which the reference voltage generator 125 changes the second reference voltage V2 is considerably slower than an operation speed of the XOR gate 141, and the second reference voltage V2 may be allowed to change after the digital code value of the counter 151 reaches a predetermined value, thereby securing a sufficient time required to change the second reference voltage V2.

Meanwhile, in the eye opening monitoring apparatus according to an embodiment of the present disclosure, the second sampler 120, the comparison block 140, and the control logic block 150 may form a loop, so a “sampling-comparison-second reference voltage change” process may be repeated.

For instance, assuming that the digital code of the counter 151 increases by 1 each time the XOR gate 141 outputs 0, counting may be continuously performed for the second reference voltage V2 increased by one step, and when the digital code value of the counter 151 becomes “00010 00000,” the second reference voltage V2 may be increased by one step again. Additionally, when the digital code value of the counter 151 becomes “00011 00000,” the second reference voltage V2 begins to increase by one step again. In case where the second reference voltage V2 is increased by three steps through this process and at this time, the output value of the second sampler 120 and the output value of the first sampler 110 is different, the output value of the XOR gate 141 becomes 1. Each time the XOR gate 141 outputs 1, the counter 151 may decrease the digital code value by 1. Then, when the digital code value of the counter 151 becomes “00010 11111,” the control logic block 150 may generate a control command signal EVo to decrease the second reference voltage V2 by one step.

In this manner, a boundary line of the eye diagram 10 (e.g., a boundary line with a probability of 50% error occurrence) may be searched, and when the boundary line is determined in the sub-clock PCLK at a specific phase, the boundary line of the eye diagram 10 may be searched by changing the phase of the sub-clock PCLK and then changing the second reference voltage V2. Meanwhile, the digital code values described in this specification are provided as examples to explain the operating principle of the eye opening monitor circuit 100 according to an embodiment of the present disclosure, and may be replaced with other values as necessary.

The eye opening monitor circuit 100 according to an embodiment of the present disclosure may collect information required to generate the eye diagram 10, and in this process, a line width thickness of the eye diagram 10 may be adjusted.

In one embodiment, an error rate control signal Sc1 may be applied to the control logic block 150. The error rate control signal Sc1 may include information that sets a target value of an output error rate.

In one embodiment, increase and decrease widths of the counter 151 may be set to different values according to the target value of the output error rate. For example, in case of finding a boundary line at the top of the eye with a target error rate of 25%, when the loop is operated with a ratio of increase and decrease widths of 3:1, the boundary line will express an error rate of 25% in an equilibrium state. In one embodiment, the control logic block 150 may adjust the increase and decrease widths of the counter 151 in a manner of adjusting the weight of the counter 151.

In one embodiment, once the target error rate is set, a boundary line corresponding to the target value of the output error rate may be derived.

In one embodiment, the eye opening of the eye diagram 10 becomes narrow when the target value of the output error rate is relatively small, and the eye opening becomes wide when the target value of the output error rate is relatively large. When the boundary line of the eye diagram 10 is extracted twice with two target values, a thickness of the boundary line of the eye diagram 10 may be extracted. A line width of the eye diagram 10 becomes relatively thick when a difference between the two target values for the same signal is set to be large, and the line width of the eye diagram 10 becomes relatively thin when the difference between the two target values is set to be small. FIG. 7 illustrates a second border line BA2 having a relatively wide line width and a first border line BA1 having a relatively narrow line width in the eye diagram 10, and in one embodiment, the first boundary line BA1 may be obtained when the output error rate is set to 50%, and the second boundary line BA2 may be obtained when the output error rate is set to two values, one smaller than 50% and one larger than 50% (e.g., 30% and 70%).

The eye opening monitor circuit 100 according to an embodiment of the present disclosure may further include an eye diagram generator. In one embodiment, the eye diagram generator may perform a function of generating the eye diagram 10 using the above-described control command signal EVo, or the like.

Referring to FIG. 9, the counting information of the counter 151 may consist of a digital code value including most significant bit information CNT_bit1 and least significant bit information CNT_bit2. Here, as illustrated in FIG. 8, the most significant bit information CNT_bit1 may be fed back to the reference voltage generator 125, and accordingly, the most significant bit information CNT_bit1 may be fed back to a loop consisting of the reference voltage generator 125, the second sampler 120, the comparison block 140, and the control logic block 150.

Additionally, the most significant bit information CNT_bit1 may be provided to an outside of the above-described loop and utilized to generate an eye diagram. For instance, most significant bit information CNT_bit1 may be provided to the above-described eye diagram generator and utilized to generate the eye diagram 10.

In one embodiment, the least significant bit information CNT_bit2 does not have a separate effect on the above-described loop, but may be provided an outside of the above-described loop and utilized to increase a resolution of the eye diagram 10. For instance, the least significant bit information CNT_bit2 may be provided to the above-described eye diagram generator and utilized to improve the resolution of the eye diagram 10.

In one embodiment, the most significant bit information CNT_bit1 and the least significant bit information CNT_bit2 may be used together to generate a high-resolution eye diagram 10 through a moving average technique or the like.

In one embodiment, when a boundary line having a line width has been extracted, a line width expressed from 0% to 100% may be estimated from the previously extracted line width using linear or Gaussian characteristics.

FIG. 4 is a diagram for explaining a chiplet structure 1000 in which the eye opening monitor circuit 100 is utilized according to an embodiment of the present disclosure. Referring to FIG. 4, the eye opening monitor circuit 100 may be applied to a D2D interface 200 that allows communication between each chip (or die) in a chiplet-based system. For instance, an input/output chip 300, a core chip 400, a memory chip 500, and the like may constitute a chiplet structure 1000, the D2D interface 200 may be constructed on the communication channel 3 for transmitting and receiving data between those chips, the eye opening monitor circuit 100 may be applied to the D2D interface 200, and an eye opening monitoring result may be utilized for the purpose of evaluating and improving the quality of a signal according to an environment of each channel. Here, standard technologies related to the D2D interface 200 may include UCLe, and the chiplet structure 1000 may also be mounted on a high-bandwidth memory (HBM).

Meanwhile, as illustrated in FIG. 4, in the chiplet structure 1000, a plurality of parallel lanes (lane-1, lane-2, . . . , lane-M) may be used in the D2D interface 200. Here, the number of parallel lanes may reach 64 (e.g., M=64). In order to perform EOM for such a large number of lanes, providing a large number of the eye opening monitor circuits 100 may be inefficient in terms of reduction in size and low power consumption of the chiplet. As illustrated in FIG. 4, one eye opening monitor circuit 100 may be provided to allow the eye opening monitor circuit 100 to perform eye opening monitoring for each of a plurality of lanes, thereby reducing an area and power consumption occupied by the eye opening monitor circuit 100 in the chiplet structure 1000. In addition, in a case where eye opening monitoring is performed for a plurality of lanes as in the chiplet structure 1000, but the eye opening monitor circuit 100 must be minimized for reduction in size and low power consumption, it can be seen that the importance of shortening a processing time required for eye opening monitoring further increases. For instance, assuming that a time required for eye opening monitoring for one lane is 0.3 μs, a time required to perform EOM for the D2D interface 200 consisting of 64 lanes will be 19.2 μs. The eye opening monitor circuit 100 according to an embodiment of the present disclosure may reduce a time required for eye opening monitoring compared to the related art, and it is to be understood that the effective value is higher in the chiplet structure 1000 in which a plurality of D2D interfaces 200 including a plurality of parallel lanes are provided.

The eye opening monitor circuit 100 with a feedback loop according to an embodiment of the present disclosure may be provided with a retimer that adjusts the timing of an output value of the first sampler 110 and an output value of the second sampler 120 at the input terminal of the comparison block 140, and accordingly, an error occurring due to a timing difference between the output value of the first sampler 110 and the output value of the second sampler 120 may be prevented.

In one embodiment, referring to FIG. 10, the retimer may be implemented as a flip-flop. For instance, an output terminal of the first sampler 110 may be connected to an input terminal of the first flip-flop 171, and an output terminal of the first flip-flop 171 may be connected to an input terminal of the comparison block 140. In addition, an output terminal of the second sampler 120 may be connected to an input terminal of the second flip-flop 172, and an output terminal of the second flip-flop 172 may be connected to an input terminal of the comparison block 140.

Referring to FIGS. 10 and 11, an output of the first sampler 110 and an output of the second sampler 120 may be received by the first flip-flop 171 and the second flip-flop 172, respectively, and the outputs of the first flip-flop 171 and the second flip-flop 172 may be adjusted by clock signals provided to the first flip-flop 171 and the second flip-flop 172, thereby solving a problem due to a timing difference between an output value of the first sampler 110 and an output value of the second sampler 120. The first sampler 110 samples a signal at an edge of the main clock MCLK, and the second sampler 120 samples a signal at an edge of the sub-clock PCLK, and there is a timing difference of Td1 between the main clock MCLK and the sub-clock PCLK. The first flip-flop 171 and the second flip-flop 172 receive the output signals of the first sampler 110 and the second sampler 120, respectively, and then output the received output signals according to a predetermined timing. For instance, the first flip-flop 171 delays an output value of the first sampler 110 by Td2 to output the delayed output value, and the second flip-flop 172 delays an output value of the second sampler 120 by Td3 to output the delayed output value. Here, there is a relationship of Td2+Td1=Td3. Accordingly, the problem of garbage data being generated in a comparison result value output by the comparison block 140 due to a timing difference as much as Td1 may be solved.

In another embodiment, referring to FIGS. 12 and 13, the retimer may be implemented as a third flip-flop 173 connected to an output terminal of the comparison block 140. As the third flip-flop 173 is provided, corrected data (D2 in FIG. 13) may be obtained to remove the garbage data (D1 in FIG. 13) of the comparison block 140, and as a result, an error occurring due to a timing difference between the output value of the first sampler 110 and the output value of the second sampler 120 may be prevented. Meanwhile, the output terminal of the first sampler 110 may be connected to an input terminal of a first delay circuit 181, and an output terminal of the first delay circuit 181 may be connected to the input terminal of the comparison block 140. In addition, the output terminal of the second sampler 120 may be connected to an input terminal of a second delay circuit 182, and an output terminal of the second delay circuit 182 may be connected to the input terminal of the comparison block 140. Here, a degree of delay of the first delay circuit 181 and the second delay circuit 182 may be the same (e.g., Td4=Td5 in FIG. 13). In one embodiment, the first delay circuit 181 and the second delay circuit 182 may be required when the comparison block 140 operates in response to the enable signal EN.

An eye opening monitoring method according to an embodiment of the present disclosure includes steps A, B, C, and D.

In one embodiment, step A is performed in a manner of outputting, by the first sampler 110, a first digital value sampled by comparing the input signal V1 with the first reference voltage Vcm, and outputting, by the second sampler 120, a second digital value sampled by comparing the input signal V1 with the second reference voltage V2.

In one embodiment, step B is performed in a manner of comparing, by the comparison block 140, the first digital value with the second digital value to output a comparison result value.

In one embodiment, step C is performed in a manner of generating, by the control logic block 150, a control command signal EVo to change the second reference voltage V2.

In one embodiment, step D is performed in a manner of being fed back to the step A subsequent to the step C.

In one embodiment, the control logic block 150 may generate a control command signal EVo to change the second reference voltage V2 in a direction in which a difference between the first reference voltage Vcm and the second reference voltage V2 increases when the first digital value and the second digital value are the same, and generate a control command signal EVo to change the second reference voltage V2 in a direction in which the difference between the first reference voltage Vcm and the second reference voltage V2 decreases when the first digital value and the second digital value are different.

In one embodiment, step C may be ended when a predetermined condition is satisfied.

The eye opening monitoring method according to an embodiment of the present disclosure may further include step B1, and in step B1, an edge at which the first digital value changes may be detected. When the edge is detected in step B1 in this manner, the step B may be performed.

The eye opening monitoring method according to an embodiment of the present disclosure may further include step E, and in step E, the eye diagram 10 may be generated using the control command signal EVo.

Here, the counting information of the counter 151 may consist of a digital code value including most significant bit information CNT_bit1 and least significant bit information CNT_bit2, the most significant bit information CNT_bit1 may be used to change the second reference voltage V2, the most significant bit information CNT_bit1 may be utilized to generate the eye diagram 10 in the step E, and the least significant bit information CNT_bit2 may be utilized to increase a resolution of the eye diagram 10 in the step E.

The eye opening monitoring method according to an embodiment of the present disclosure may repeatedly perform steps A, B, C, and D while increasing the second reference voltage V2 by starting from the center of the eye diagram 10 through repeatedly performing the above-described steps A to D.

In one embodiment, subsequent to carrying out a reference voltage change search process of checking the digital code value when the first digital value and the second digital value become different, the method may change the phase while maintaining the second reference voltage V2 that is finally used in the reference voltage change search process, and then repeatedly perform steps A to D.

Referring to FIG. 14, assuming that the second reference voltage V2 is changed once in searching for a boundary line of the eye diagram 10 by starting from a position indicated by \textcircled{1}, the reference voltage V2 must be increased by two arrows again from position \textcircled{2} by changing the phase to search the boundary line of the eye diagram 10. Here, assuming that a time required to move one arrow 15 is about 10 ns, it takes approximately 200 ns when carrying out in a manner illustrated in FIG. 14.

In FIG. 15, the boundary line of the eye diagram 10 may be searched by starting from the position indicated by \textcircled{1}, and it may take approximately 70 ns when searching the boundary line of the eye diagram 10 in the order of \textcircled{2}, \textcircled{3}, \textcircled{4}, \textcircled{5}, \textcircled{6}, \textcircled{7}, \textcircled{8}, and \textcircled{9}.

In this manner, when applying the eye opening monitoring method according to an embodiment of the present disclosure, information required to generate the eye diagram 10 may be collected more rapidly.

The eye opening monitor circuit 100 according to an embodiment of the present disclosure may perform eye opening monitoring even with random data being received in real time.

In addition, based on the set target value of the output error rate, the position of a point according to voltage and time axes, which satisfies the corresponding output error rate, may be rapidly found on the eye diagram 10.

Additionally, the eye opening monitor circuit 100 according to an embodiment of the present disclosure may rapidly measure an output error rate at an edge portion of data by utilizing the edge detector 130.

In addition, position information at a rising edge of data and a falling edge of data may be obtained by using the feedback loop and the edge detector 130.

Additionally, the target value of the output error rate may be changed, and thus a line width of the eye diagram 10 may be adjusted.

The present disclosure has been described with reference to an embodiment illustrated in the accompanying drawings, but the embodiment is merely illustrative, and is not limited to the above-described embodiments, and it should be appreciated by those skilled in the art that various modifications and other embodiments equivalent thereto can be made therefrom. Therefore, the true protective scope of the present disclosure should be determined only by the appended claims.

### DESCRIPTION OF REFERENCE CHARACTERS

10: Eye diagram
100: Eye opening monitor circuit
110: First sampler
120: Second sampler
125: Reference voltage generator
127: Sub-clock generator
130: Edge detector
140: Comparison block
141: XOR gate
150: Control logic block
151: Counter
171: First flip-flop
172: Second flip-flop
173: Third flip-flop
181: First delay circuit
182: Second delay circuit
1000: Chiplet structure
200: D2D interface
220: Equalizer
230: Clock-data recovery circuit
300: Input/output chip
400: Core chip
500: Memory chip
V1: Input signal
V2: Second reference voltage
Vcm: First reference voltage
EN: Enable signal
Sc1: Error rate control signal
MCLK: Main clock
PCLK: Sub-clock
CNT_bit1: Most significant bit information
CNT_bit2: Least significant bit information

What is claimed is:

1. An eye opening monitor circuit configured to measure information for generating an eye diagram with respect to at least one point of a transmission apparatus or reception apparatus, the eye opening monitor circuit comprising:
a first sampler (110) that samples a data value by comparing an input signal V1 with a first reference voltage Vcm;
a second sampler (120) that samples a data value by comparing the input signal with a second reference voltage V2;
a comparison block (140) that compares an output value of the first sampler with an output value of the second sampler to output a comparison result value; and
a control logic block (150) that generates a control command signal EVo to change the second reference voltage,
wherein the control logic block generates a control command signal to change the second reference voltage in a direction in which a difference between the first and second reference voltages increases when the output value of the first sampler and the output value of the second sampler are the same, and generates a control command signal to change the second reference voltage in a direction in which the difference between the first and second reference voltages decreases when the output value of the first sampler and the output value of the second sampler are different, and wherein the second sampler, the comparison block, and the control logic block form a loop.

2. The eye opening monitor circuit of claim 1, further comprising:
an edge detector (130) that detects an edge at which the output value of the first sampler changes,
wherein the edge detector provides an enable signal EN to the comparison block when a change in the output value of the first sampler is detected.

3. The eye opening monitor circuit of claim 2, wherein the comparison block comprises an XOR gate (141) in which an output terminal of the first sampler is connected to a first input terminal and an output terminal of the second sampler is connected to a second input terminal,
wherein the control logic block comprises a counter (151) connected to an output terminal of the XOR gate,
wherein the XOR gate operates when the enable signal is applied thereto, and
wherein the control logic block generates the control command signal according to a digital code value of the counter.

4. The eye opening monitor circuit of claim 3, wherein the XOR gate outputs 0 when input values of the first input terminal and the second input terminal are the same, and outputs 1 when they are different,
wherein the counter increases the digital code value when an output value of the XOR gate is 0,
wherein the counter decreases the digital code value when the output value of the XOR gate is 1, and
wherein the control logic block generates a control command signal to change the second reference voltage when the digital code value reaches a predetermined value.

5. The eye opening monitor circuit of claim 1, further comprising:
a reference voltage generator (125) that generates the second reference voltage,
wherein the reference voltage generator determines the second reference voltage according to the control command signal.

6. The eye opening monitor circuit of claim 3, wherein a ratio of increase and decrease widths of the digital code value is determined according to a target value of an output error rate,
wherein when the target value of the output error rate is a first target value, an eye opening of the eye diagram is relatively small, and
wherein when the target value of the output error rate is a second target value greater than the first target value, the eye opening of the eye diagram is relatively large.

7. The eye opening monitor circuit of claim 3, wherein the counting information of the counter consists of a digital code value including most significant bit information CNT_bit1 and least significant bit information CNT_bit2,
wherein the most significant bit information is fed back to the loop,
wherein the most significant bit information is utilized to generate the eye diagram outside the loop, and
wherein the least significant bit information is utilized to increase a resolution of the eye diagram outside the loop.

8. The eye opening monitor circuit of claim 3, further comprising:
an eye diagram generator that generates an eye diagram using the control command signal,
wherein the counting information of the counter consists of a digital code value including most significant bit information and least significant bit information,
wherein the most significant bit information is fed back to the loop,
wherein the most significant bit information is provided to the eye diagram generator outside the loop and utilized to generate the eye diagram, and
wherein the least significant bit information is provided to the eye diagram generator outside the loop and utilized to increase a resolution of the eye diagram.

9. An eye opening monitoring method, the method comprising:
a step A of outputting, by a first sampler, a first digital value sampled by comparing an input signal with a first reference voltage, and outputting, by a second sampler, a second digital value sampled by comparing the input signal with a second reference voltage;
a step B of comparing, by a comparison block, the first digital value with the second digital value to output a comparison result value;
a step C of generating, by a control logic block, a control command signal to change the second reference voltage; and
a step D of being fed back to the step A subsequent to the step C,
wherein the control logic block generates a control command signal to change the second reference voltage in a direction in which a difference between the first and second reference voltages increases when the first digital value and the second digital value are the same, and generates a control command signal to change the second reference voltage in a direction in which the difference between the first and second reference voltages decreases when the first digital value and the second digital value are different, and
wherein the step C is ended when a predetermined condition is satisfied.

10. The method of claim 9, further comprising:
a B1 step of detecting an edge at which the first digital value changes,
wherein the step B is performed when the edge is detected in the step B1.

11. The method of claim 9, wherein the comparison block comprises an XOR gate,
wherein the XOR gate is configured such that an output terminal of the first sampler is connected to a first input terminal and an output terminal of the second sampler is connected to a second input terminal so as to output 0 when the first digital value and the second digital value are the same, and 1 when they are different,
wherein the control logic block comprises a counter that outputs a digital code value,
wherein the counter increases the digital code value when an output value of the XOR gate is 0,
wherein the counter decreases the digital code value when the output value of the XOR gate is 1, and
wherein the control logic block generates a control command signal to change the second reference voltage when the digital code value reaches a predetermined value.

12. The method of claim 11, further comprising:
a step E of generating an eye diagram using the control command signal;
wherein the counting information of the counter consists of a digital code value including most significant bit information and least significant bit information,
wherein the most significant bit information is used to change the second reference voltage,
wherein the most significant bit information is utilized to generate the eye diagram in the step E, and
wherein the least significant bit information is utilized to increase a resolution of the eye diagram in the step E.

13. The method of claim 11, further comprising, subsequent to carrying out a reference voltage change search process of checking the digital code value when the first digital value and the second digital value become different through repeatedly performing the steps A, B, C and D while increasing the second reference voltage by starting from the center of the eye diagram,
maintaining the second reference voltage that is finally used in the reference voltage change search process and changing a phase thereof, and then repeatedly performing the steps A, B, and C.

14. An eye opening monitor circuit configured to measure information for generating an eye diagram with respect to at least one point of a transmission apparatus or reception apparatus, the eye opening monitor circuit comprising:
a first sampler (110) that samples a data value by comparing an input signal V1 with a first reference voltage Vcm at an edge of a main clock MCLK;
a second sampler (120) that samples a data value by comparing the input signal with a second reference voltage V2 at an edge of a sub-clock PCLK;
a comparison block (140) that compares an output value of the first sampler with an output value of the second sampler to output a comparison result value; and
a control logic block (150) that generates a phase control command signal EPo to change a phase of the sub-clock,
wherein the control logic block generates a phase control command signal to change the sub-clock in a direction in which a difference between the main clock and the sub-clock increases when the output value of the first sampler and the output value of the second sampler are the same, and generates a phase control command signal to change the sub-clock in a direction in which the difference between the main clock and the sub-clock decreases when the output value of the first sampler and the output value of the second sampler are different, and
wherein the second sampler, the comparison block, and the control logic block form a loop.
